(19) United States
(12) Patent Application Publication
(10) Pub. No.: US 2006/0213770 A1
(43) Pub. Date: Sep. 28, 2006

(54) Sputtering device

(76) Inventor: Nobuyuki Takahashi, Sagamihara (JP)

Correspondence Address: WENDEROTH, LIND & PONACK, L.L.P., 2033 K STREET N. W., SUITE 800, WASHINGTON, DC, 20006-1021, US

(21) Appl. No.: 11/224,063

(22) Filed: Sep. 13, 2005

(30) Foreign Application Priority Data
Mar. 25, 2005 (JP) 2005-089162

(51) Int. Cl. C23C 14/00

(52) U.S. Cl. 204/298.15

(57) ABSTRACT

An object of the invention is to provide a sputtering device which can increase forming film distribution and coverage distribution without enlarging a size thereof. Accordingly, the present invention is a sputtering device comprising at least: a vacuum chamber; a sputtering cathode secured in said vacuum chamber; and a substrate holder unit installing a substrate on which thin film is formed with particles sputtered from said sputtering cathode, wherein said substrate holder unit comprises: a substrate supporting portion on which the substrate is installed; a heater mechanism which is provided in said substrate support portion and heats the substrate; a cooling mechanism for cooling said heater mechanism; a bias applying mechanism for applying bias voltage to said substrate supporting portion; an arcuate moving base to which said heater mechanism, said cooling mechanism and said bias applying mechanism are secured and which supports said substrate supporting portion rotatably; an eccentric shaft which extends from said arcuate moving base eccentrically relative to a rotation center of said substrate supporting portion and is supported in said vacuum chamber rotatably; a rotation mechanism which is provided through said eccentric shaft and makes said substrate supporting portion rotate; and an arcuate moving mechanism for rotating said eccentric shaft.

### BACKGROUND OF THE INVENTION

The present invention relates to a sputtering device which is constituted of a substrate and a target for forming a thin film on the substrate and in which ionized gas rushes into the target to sputter atoms or molecules from the substrate and sputtered atoms or molecules are adhered on the substrate to form the thin film on the substrate.

JP 11-335835 A discloses that: a circular target which is a forming film material is arranged so as to face a substrate for a thin film to be formed in order to increase evenness of film thickness, the substrate rotates around a center thereof as a rotation shaft as it moves arcuately over the target, and the substrate is revolved so that a position where the substrate overlaps to the target is different from a position where the substrate overlapped to the target the last time when the substrate passes over the target.

JP 2001-262336 A discloses that insulation thin film is formed by adjusting impedance of a second matching circuit so as to bring a direct current component of an electrical potential of the substrate holder unit close to a plasma electrical potential in order to secure film thickness evenness in a wide range over a large scaled substrate, and that an angle is given between the target and the substrate holder unit and they are arranged so as to shift their centers respectively.

JP 2002-20864 A discloses a sputtering device that a substrate and a target are arranged so that sputtering particles are incident aslant to the substrate and the substrate is revolved in order to form magnetic thin film with high anisotropic rate in good uniformity.

JP 2002-20866 A discloses that: in a sputtering device in which magnetic field is formed on a target and electric field is applied to the target to sputter an object and a means for generating magnetic field is arranged near the target, and which comprises a plurality of magnets which are operated in combination of rotation and arcuate movement.

In the sputtering device disclosed in JP 11-335835 A, though a target is made larger than a substrate in order to increase film thickness distribution on the substrate, since bias of film thickness formed in concave portions is arisen in the case that there are uneven on the substrate, a problem such that coverage distribution gets worse is arisen.

Besides, in the sputtering device disclosed in JP 2001-262336 A, a distance between a surface of the substrate and the target is uneven, even if the substrate is rotated and moved arcuately, a potential difference control between the cathode and the target and an impedance control of the matching circuit must be carried out delicately, so that a disadvantage such that the control itself becomes very complicated is arisen.

Furthermore, in the sputtering device disclosed in JP 2002-20864 A, since particles sputtered from the target are limited by a distribution modified plate, it is achieved to form thinner film on the substrate, but a problem such that utilization of the target is worst is arisen. Besides, since a center portion of the substrate is a common portion, a problem such that film thickness in the center portion is thicker than the other portion is arisen.

Moreover, the sputtering device disclosed in JP 2002-20866 A is that a plurality of magnets arranged behind the target is made rotating and revolving complexly to change magnetic field complexly, so that an erosion area of the target becomes uniform. However, since complex change of the magnetic field makes electrons which are moved cyclonically on the target further complex movement, the magnetic field and the electric field become irregular. Thus, the erosion area of the target is even, but flying directions of the target atoms become uneven. Accordingly, a problem such that film thickness distribution and coverage distribution of the substrate become uneven is arisen.

Besides, recently, for increasing functions of devices, it is desired in markets to increase film thickness distribution. For instance, it is desired to be not more than 3% of the film thickness distribution against not more than 5% of the prior film thickness distribution. Thus, in prior arts, the desire is satisfied by adjusting a distance between the target and the substrate. However, when the distance between the target and the substrate is brought too close, a disadvantage such that the substrate undergoes plasma damage by sputtering discharge or a disadvantage such that a substrate holder unit is influenced by temperature increase by the sputtering discharge are arisen. Furthermore, when the target is detached from the substrate, a disadvantage such that the film thickness becomes worse is arisen generally. Thus, adjustment of the distance is very difficult operation.

Furthermore, when a sputtering area is spread by enlarging a size of a sputtering target material in order to improve the film thickness distribution, a disadvantage such that a sputtering device itself is enlarged, and further enlarging the sputtering target material arises disadvantages of an increase in costs of the sputtering target material and an increase in running costs because of increasing electric power consumption of a sputtering power source.

### SUMMARY OF THE INVENTION

An objection of the present invention is to provide a sputtering device which can increase film thickness distribution and coverage distribution without enlarging a size thereof.

Accordingly, the present invention is a sputtering device comprising at least a vacuum chamber, a sputtering cathode fixed in the vacuum chamber, and a substrate holder unit installing a substrate on which thin film is formed by particles sputtered from the sputtering cathode, wherein the substrate holder unit comprises at least a substrate supporting unit on which the substrate is installed, a heater mechanism which is provided on the substrate supporting portion and heats the substrate, a cooling mechanism for cooling the heater mechanism, a bias applying mechanism for apply bias voltage to the substrate, an arcuate moving base to which the heater mechanism, the cooling mechanism and the bias applying mechanism are fixed and which supports the substrate supporting unit rotatably, an eccentric shaft extending from the arcuate moving base eccentrically to a rotation center of the substrate supporting unit and supported on the vacuum chamber rotatably, a rotation mechanism providing through the eccentric shaft and rotating the substrate supporting unit, and an arcuate movement mechanism for rotating the eccentric shaft.

It is preferred that the substrate supporting unit is constituted of a substrate supporting plate on which the substrate is installed, and a rotation block on which the substrate supporting plate is secured and which is supported on the arcuate moving base rotatably. Furthermore, it is preferred that an opening communicating between the substrate and the heater mechanism is formed in the substrate supporting plate. Besides, it is more preferred that a shied portion is provided around an outer periphery of the rotation block and the substrate supporting plate with a specific space.

Furthermore, it is preferred that piping holes are formed in the rotation block, the arcuate moving base and the eccentric shaft to communicate inside them in succession, and that at least wiring for the heater mechanism, piping for the cooling mechanism and wiring constituting a part of the bias applying mechanism are arranged in the piping holes.

Moreover, it is preferred that the rotation mechanism is constituted of a rotation shaft passing through the piping hole formed inside the eccentric shaft and the arcuate moving base, a rotation driving means for rotating the rotation shaft, and rotation gear mechanism for transmitting rotation of the rotation shaft to the rotation block.

According to the present invention, as the substrate installed on the substrate holder unit is rotated and moved arcuately to the sputtering cathode fixed on the vacuum chamber, a distance and position between the substrate and the sputtering cathode can be changed, so that good film thickness distribution and good coverage distribution on the substrate can be achieved. Besides, according to the present invention, when the sputtering target material is smaller than the substrate, available forming film distribution can be gained. Furthermore, since it is not necessary to adjust the distance between the sputtering target material and the substrate, it is easy to improve the forming film distribution by difference of the sputtering target material and speed in development can be increased, so that device development can be promoted.

Furthermore, because the opening portion communicating between the substrate and the heater mechanism is provided, the substrate is heated efficiently. Besides, because the cooling mechanism is provided between the heater mechanism and the substrate holder unit, thermal influence by the heater mechanism can be prevented, so that rotation and arcuate movement of the substrate holder unit can be operated smoothly.

### BRIEF DESCRIPTION OF DRAWINGS

FIG. 1 is a schematic diagram of the sputtering device according to the present invention;

FIG. 2 is a schematic diagram of the substrate holder unit of the sputtering cathode; and

FIGS. 3A and 3B are schematic diagram showing a position of the substrate holder unit and the substrate to a radiation opening of the sputtering cathode, especially FIG. 3A shows a condition that the substrate faces to the radiation opening and FIG. 3B shows a condition that the substrate moves arcuately.

### DETAILED DESCRIPTION OF THE PREFERRED WORKING MODE

Hereinafter, a working mode of the present invention is explained by referring drawings.

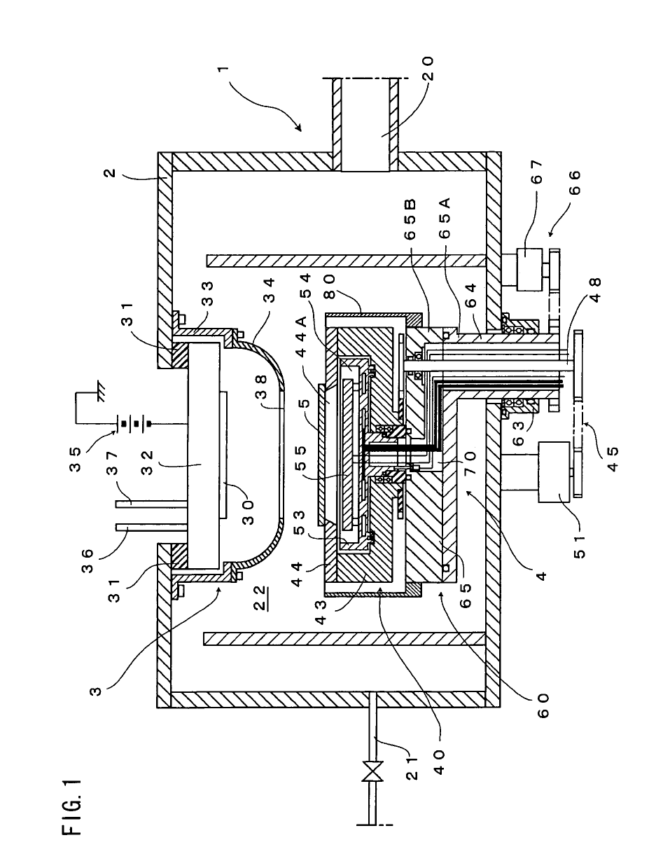

A sputtering device shown in FIG. 1 comprises a vacuum chamber 2, a sputtering cathode unit 3 fixed in the vacuum chamber 2, and a substrate holder unit 4 holding a substrate 5.

The sputtering cathode unit 3 is constituted of at least an electrode 32 attached via an insulator 31 on the vacuum chamber 2, a sputtering target material 30 attached on the electrode 32, a first earth shield portion 33 provided around the electrode 32, a second earth shield portion 34 which is extended from the first earth shield portion 33 and in which a radiation opening 38 is formed, a sputtering power source 35 for supplying DC power (or high frequency electric power) to the electrode 23 and pipes for cooling water 36, 37 for supplying cooling water for restricting temperature by heat of sputtering.

Besides, an exhaust opening for vacuum 20 connected to a vacuum exhaust pump not shown in figures is formed and a gas supply pipe 21 for supplying gas introduced at forming film by sputtering in the vacuum chamber 35.

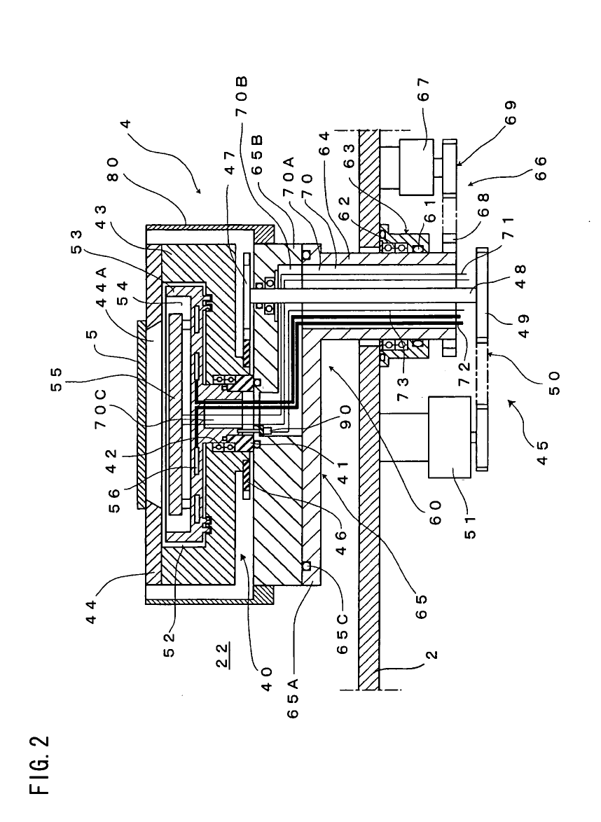

The substrate holder unit 4 is, as shown in FIG. 2, constituted of a rotation mechanism 40 and an arcuate movement mechanism 60 for moving the substrate 5 arcuately to the sputtering cathode 3.

The arcuate movement mechanism 60 is constituted of an eccentric shaft 64 installed rotatably in the vacuum chamber 2 via a holding mechanism 63 which comprises seal portion 61 and a bearing portion 62, an arcuate moving base 65 installed eccentrically to the eccentric shaft 64, and an arcuate movement driving mechanism 66 for rotating the eccentric shaft 64. Besides, the arcuate movement driving mechanism 66 comprises an electric motor 67, a gear 68 formed around the eccentric shaft 64, and a rotation transmission mechanism 69.

Furthermore, the arcuate moving base 65 is constituted of a lower base member 65A which is formed with the eccentric shaft 64 unitedly and has a first piping hole 70A formed inside the eccentric shaft 64 and an upper base member 65B having a second piping hole 70B communicating to the first piping hole 70A. The first base member 65A is fixed to the second member 65B via a seal portion 65C. Besides, a through hole through which a rotation shaft 48 mentioned below passes is formed on an extending line of the first piping hole 70A in the upper base member 65B, and a bearing and seal portion are arranged around thereof so as to hold the rotation shaft 48 rotatably. Furthermore, a shield 80 extending above is provided around the upper base member 65B. Moreover, a supporting shaft 41 consisting of an insulator is secured on the upper base member 65B so as to stand in a center portion thereof.

The rotation mechanism 40 is constituted of a rotation block 43 supported rotatably via a bearing portion 42 to the supporting shaft 41 and a rotation driving mechanism 45 for rotating the rotation block 43.

The rotation driving mechanism 45 is constituted of a rotation gear 46 formed on the rotation block 43, a first driving gear 47 engaging with the rotation gear 46, the rotation shaft 48 on whose one end the first driving gear 47 is fixed, a second driving gear 49 fixed on the other end of the rotation shaft 48, and an electric motor 51 connected via a connection mechanism 50 to the second driving gear 49. Besides, the rotation gear 46 consists of an insulator.

A temperature control base 53 secured and supported to the supporting shaft 41 is provided in a space 52 defined inside the rotation block 43 and enclosed by a substrate supporting plate 44, and a heating source 55 such as a heater is provided in an inner space 54 of the temperature control base 53. The temperature control base 53 is cooled down by a cooling mechanism 56 in order to protect the bearing portion 42 and so on. Furthermore, an opening 44A communicating between the substrate 5 and the heating source 55 is provided in the substrate supporting plate 44.

Besides, a wiring for heater 71 connecting to the temperature control base 53, a piping 72 for supplying and draining fluid for cooling (in this embodiment, cooling water) to the cooling mechanism 56, and a bias wiring 73 to a terminal 90 for introducing a bias voltage to the rotation block 43 pass through piping holes 70, which comprises a third piping hole 70C formed inside the supporting shaft 41, the second piping hole 70B formed in the upper base member 65B and the first piping hole 70A formed in the eccentric shaft 64 of the lower base member 65A, in turn to connect to an outside. Besides, the terminal 90 is fixed to the upper base member 65B via an insulator, and passes through the upper base member 65B to connect with the rotation block 43, and further the bias voltage is applied via the rotation block 43 and the substrate supporting plate 44 (a bias applying mechanism).

By thus the constitution, even if the wiring 71, piping 72 and the bias wiring 73 are provided, the rotation block 43 can be rotated and can be moved arcuately around the eccentric shaft 64.

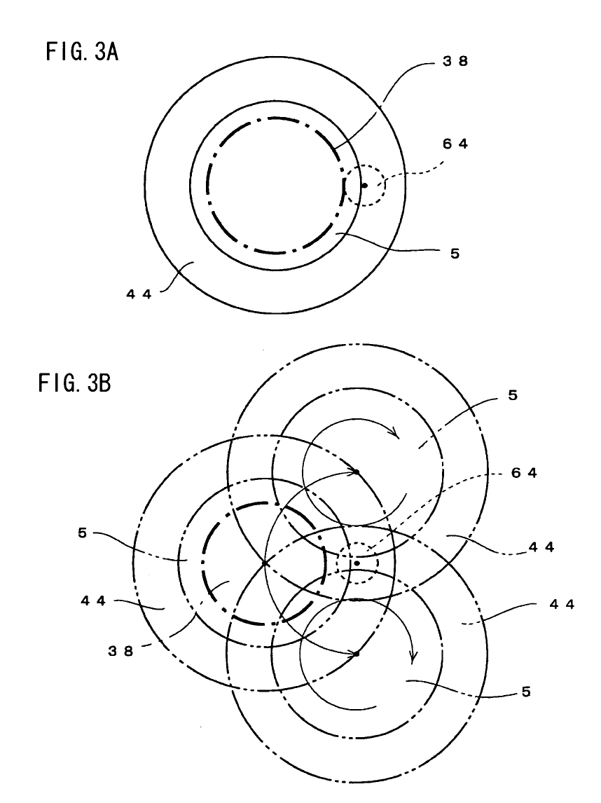

Accordingly, due to the above mentioned constitution, when the substrate 5 installed on the substrate supporting plate 44 is moved to a position facing to the radiation opening 38 of the sputtering cathode unit 3, for instance arrangement as shown in FIG. 3A is achieved. Furthermore, by that the rotation mechanism 40 and the arcuate movement mechanism 60 are operated simultaneously, as shown in FIG. 3B, the substrate 5 is rotated and moved arcuately to the radiation opening 38 of the sputtering cathode 3. Accordingly, when the size of the sputtering target 30 is smaller than one of substrate 5, available forming film distribution van be gained.

What is claimed is:

1. A sputtering device comprising at least:
a vacuum chamber;
a sputtering cathode secured in said vacuum chamber; and
a substrate holder unit installing a substrate on which thin film is formed with particles sputtered from said sputtering cathode,
wherein said substrate holder unit comprises:
a substrate supporting portion on which the substrate is installed;
a heater mechanism which is provided in said substrate support portion and heats the substrate;
a cooling mechanism for cooling said heater mechanism;
a bias applying mechanism for applying bias voltage to said substrate supporting portion;
an arcuate moving base to which said heater mechanism, said cooling mechanism and said bias applying mechanism are secured and which supports said substrate supporting portion rotatably;
an eccentric shaft which extends from said arcuate moving base eccentrically relative to a rotation center of said substrate supporting portion and is supported in said vacuum chamber rotatably;
a rotation mechanism which is provided through said eccentric shaft and makes said substrate supporting portion rotate; and
an arcuate moving mechanism for rotating said eccentric shaft.

2. A sputtering device according to claim 1, wherein
said substrate supporting portion is constituted of a substrate supporting plate on which the substrate is installed and a rotation block which is secured on said substrate supporting plate and is supported in said arcuate moving base rotatably.

3. A sputtering device according to claim 2, wherein
an opening communicating between the substrate and said heater mechanism is formed in said substrate supporting plate.

4. A sputtering device according to claim 1, wherein
a shield portion is provided around said rotation block and said substrate supporting plate at a specific space.

5. A sputtering device according to claim 2, wherein
a shield portion is provided around said rotation block and said substrate supporting plate at a specific space.

6. A sputtering device according to claim 3, wherein
a shield portion is provided around said rotation block and said substrate supporting plate at a specific space.

7. A sputtering device according to claim 4, wherein
piping holes are formed in said rotation block, said arcuate moving base and said eccentric shaft respectively so as to communicate them successively.

8. A sputtering device according to claim 5, wherein
piping holes are formed in said rotation block, said arcuate moving base and said eccentric shaft respectively so as to communicate them successively.

9. A sputtering device according to claim 6, wherein
piping holes are formed in said rotation block, said arcuate moving base and said eccentric shaft respectively so as to communicate them successively.

10. A sputtering device according to claim 1, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.

11. A sputtering device according to claim 2, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.

12. A sputtering device according to claim 3, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.

13. A sputtering device according to claim 4, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.

14. A sputtering device according to claim 5, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.

15. A sputtering device according to claim 6, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.

16. A sputtering device according to claim 7, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.

17. A sputtering device according to claim 8, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.

18. A sputtering device according to claim 9, wherein
said rotation mechanism is constituted of a rotation shaft which passes through a piping hole formed in said eccentric shaft and said arcuate moving base, a rotation driving means for rotating said rotation shaft, and a rotation gear mechanism for transmitting rotation of said rotation shaft to said rotation block.
